(19) United States
(12) Patent Application Publication
(10) Pub. No.: US 2025/0143117 A1
(43) Pub. Date: May 1, 2025

(54) DISPLAY APPARATUS AND DISPLAY CIRCUIT BOARD

(71) Applicant: Samsung Display Co., LTD., Yongin-si (KR)

(72) Inventors: Hyeoktae KWON, Yongin-si (KR); Dongwan CHOI, Yongin-si (KR)

(21) Appl. No.: 18/795,549

(22) Filed: Aug. 6, 2024

(30) Foreign Application Priority Data
Oct. 30, 2023 (KR) 10-2023-0146995

(51) Int. Cl. H10K 59/131

(52) U.S. Cl. CPC H10K 59/131

(57) ABSTRACT

A display apparatus includes a display panel including a plurality of panel protrusions protruding from an edge of a display area and disposed apart from each other along the edge of the display area, and a display circuit board including a body portion spaced apart from the edge of the display area and extending along the edge of the display area, a plurality of connecting portions spaced apart in an extension direction of the body portion and overlapping the plurality of panel protrusions, and a board protrusion protruding from the body portion towards a concave area defined between the plurality of panel protrusions.

This application claims priority to Korean Patent Application No. 10-2023-0146995, filed on Oct. 30, 2023, and all the benefits accruing therefrom under 35 U.S.C. § 119, the content of which in its entirety is herein incorporated by reference.

### BACKGROUND

### 1. Field

Embodiments relate to a display apparatus and a display circuit board, and more particularly, to a display apparatus having a reduced non-display area and a display circuit board.

### 2. Description of the Related Art

Recently, electronic devices are being widely used. Electronic devices are widely used in various forms, such as portable and fixed configurations. Such electronic devices include display apparatuses which may provide users with visual information, such as still images or moving images, and supporting various functions.

With the recent advancements in the miniaturization of components for driving display apparatuses, the display apparatuses tend to become increasingly important in electronic devices, and thus, there is a desire to increase a display area while decreasing a non-display area.

A display circuit board may be connected to a display panel of a display apparatus to provide an electrical signal. In this case, it is desired to ensure that a non-display area does not increase according to the placement of the display circuit board.

### SUMMARY

Embodiments include a display apparatus in which a non-display area is reduced, and a display circuit board.

However, this is merely one of embodiments, and the scope of the disclosure is not limited thereto.

Additional features will be set forth in part in the description which follows and, in part, will be apparent from the description, or may be learned by practice of the presented embodiments of the disclosure.

In an embodiment of the disclosure, a display apparatus includes a display panel including a plurality of panel protrusions protruding from an edge of a display area and arranged apart from each other along the edge of the display area, and a display circuit board including a body portion spaced apart from the edge of the display area and extending along the edge of the display area, a plurality of connecting portions spaced apart in an extension direction of the body portion and overlapping the plurality of panel protrusions, and a board protrusion protruding from the body portion towards a concave area defined between the plurality of panel protrusions.

In an embodiment, the plurality of panel protrusions may include a first pad, the plurality of connecting portions may include a second pad on a portion of the plurality of connecting portions that overlaps the plurality of panel protrusions, and the first pad may contact and be electrically connected to the second pad.

In an embodiment, the plurality of connecting portions may protrude from the body portion and may overlap and be connected to the plurality of panel protrusions.

In an embodiment, a protrusion length of the board protrusion may be greater than a protrusion length of the plurality of connecting portions.

In an embodiment, the plurality of connecting portions may be provided in the number corresponding to the number of panel protrusions, and the board protrusion may be disposed between the plurality of connecting portions.

In an embodiment, the body portion, the plurality of connecting portions, and the board protrusion may be unitary with one another.

In an embodiment, in the plan view, the board protrusion may not overlap the display panel and may be spaced apart from the display panel.

In an embodiment, in the plan view, the board protrusion may have a tapered shape with a width decreasing away from the body portion.

In an embodiment, in the plan view, the board protrusion may have a quadrangular, e.g., quadrangular shape, e.g., rectangular shape with a width that is uniform away from the body portion.

In an embodiment, an extended length of the body portion may be less than a length of the edge of the display area.

In an embodiment, the body portion and the plurality of connecting portions may include a plurality of conductive layers stacked in a thickness direction of each of the body portion and plurality of connecting portions, and a conductive layer, which is a lowermost conductive layer among the plurality of conductive layers of the plurality of connecting portions, may contact and may be electrically connected to the plurality of panel protrusions.

In an embodiment, the body portion and the plurality of connecting portions may each include at least one conductive layer stacked in a thickness direction of each of the body portion and plurality of connecting portions, and a number of the at least one conductive layer in the plurality of connecting portions may be less than a number of the at least one conductive layer in the body portion.

In an embodiment, the at least one conductive layer of the body portion may be provided in plural, and a conductive layer of a plurality of conductive layers of the body portion may protrude from the body portion to form the plurality of connecting portions and may contact and may be electrically connected to the plurality of panel protrusions.

In an embodiment, the conductive layer protruding from the body portion may be an uppermost conductive layer among the plurality of conductive layers.

In an embodiment, the conductive layer protruding from the body portion may be a lowermost conductive layer among the plurality of conductive layers.

In an embodiment, the conductive layer protruding may be a middle layer among the plurality of conductive layers.

In an embodiment of the disclosure, a display circuit board connectable to a display panel includes a body portion extending in a direction, a plurality of connecting portions protruding from the body portion and spaced apart from each other in an extension direction of the body portion, and a board protrusion protruding from the body portion between the plurality of connecting portions, where the plurality of connecting portions include a pad which is electrically connected to a display panel.

In an embodiment, a protrusion length of the board protrusion may be greater than a protrusion length of the plurality of connecting portions.

In an embodiment, the body portion, the plurality of connecting portions, and the board protrusion may be unitary with one another.

In an embodiment, the body portion may include a plurality of conductive layers stacked in a thickness direction, and one of the plurality of conductive layers may protrude from the body portion to form the plurality of connecting portions.

Other features and advantages other than those described above will become apparent from the following detailed description, claims and drawings for carrying out the disclosure.

### BRIEF DESCRIPTION OF THE DRAWINGS

The above and other features and advantages of illustrative embodiments of the disclosure will be more apparent from the following description taken in conjunction with the accompanying drawings, in which:

FIG. 1 is a schematic plan view of an embodiment of a portion of a display apparatus;

FIG. 2 is a schematic side view of an embodiment of a portion of the display apparatus;

FIG. 3 is a schematic cross-sectional view taken along line III-III′ of FIG. 1 and showing an embodiment of a portion of the display apparatus;

FIG. 4 is a schematic cross-sectional view taken along line IV-IV′ of FIG. 1 and showing an embodiment of the display apparatus; and

FIGS. 5 to 7 are schematic cross-sectional views of an embodiment of a display apparatus similar to the embodiment of FIG. 4.

### DETAILED DESCRIPTION

Reference will now be made in detail to embodiments, embodiments of which are illustrated in the accompanying drawings, where like reference numerals refer to like elements throughout. In this regard, the illustrated embodiments may have different forms and should not be construed as being limited to the descriptions set forth herein. Accordingly, the embodiments are merely described below, by referring to the drawing figures, to explain features of the description. As used herein, the term “and/or” includes any and all combinations of one or more of the associated listed items. Throughout the disclosure, the expression “at least one of a, b, or c” indicates only a, only b, only c, both a and b, both a and c, both b and c, all of a, b, and c, or variations thereof.

As the disclosure allows for various changes and numerous embodiments, particular embodiments will be shown in the drawings and described in detail in the written description. The attached drawings for illustrating embodiments are referred to in order to gain a sufficient understanding of the disclosure, the merits thereof, and the objectives accomplished by the implementation of the disclosure. The disclosure may, however, be embodied in many different forms and should not be construed as being limited to the embodiments set forth herein.

Hereinafter, embodiments of the disclosure will be described in detail with reference to the accompanying drawings. Like elements in the drawings denote like elements, and repeated descriptions thereof are omitted.

It will be understood that although the terms “first,” “second,” etc. may be used herein to describe various elements, these elements should not be limited by these terms, and these elements are only used to distinguish one element from another.

As used herein, the singular forms “a,” “an,” and “the” are intended to include the plural forms as well, unless the context clearly indicates otherwise.

It will be further understood that the terms “comprises” and/or “comprising” used herein specify the presence of stated features or elements, but do not preclude the presence or addition of one or more other features or elements.

It will be understood that when a layer, region, or element is referred to as being “formed on” another layer, region, or element, it may be directly or indirectly formed on another layer, region, or element. That is, for example, intervening layers, regions, or elements may be present.

Sizes of elements in the drawings may be exaggerated for convenience of explanation. In other words, since sizes and thicknesses of elements in the drawings are arbitrarily illustrated for convenience of explanation, the following the disclosure is not limited thereto.

In the following examples, the x-axis, the y-axis and the z-axis are not limited to three axes of the rectangular coordinate system, and may be interpreted in a broader sense. For example, the x-axis, the y-axis, and the z-axis may be perpendicular to one another, or may represent different directions that are not perpendicular to one another.

When an illustrative embodiment may be implemented differently, a specific process order may be performed differently from the described order. For example, two consecutively described processes may be performed substantially at the same time or performed in an order opposite to the described order.

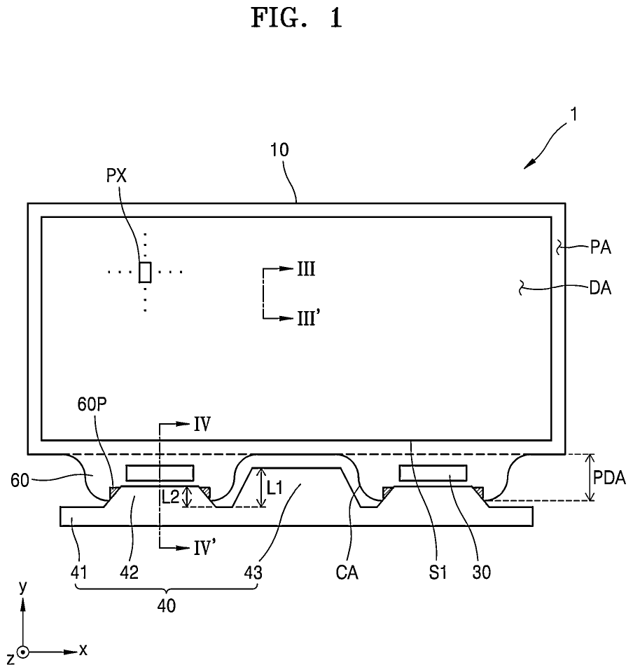

FIG. 1 is a schematic plan view of an embodiment of a portion of a display apparatus.

Referring to FIG. 1, a display apparatus 1 may display a moving image or a still image and may be used as a display screen of various products, e.g., a portable electronic device, such as a mobile phone, a smartphone, a tablet personal computer (“PC”), a mobile communication terminal, a personal digital assistant, an e-book terminal, a portable multimedia player (“PMP”), a navigation device, or an ultra-mobile PC (“UMPC”), a television (“TV”), a laptop, a monitor, a billboard, an Internet of Things (“IoT”) device, or the like. Also, in an embodiment, the display apparatus 1 may be used in a wearable device, such as a smartwatch, a watch phone, an eyewear display, or a head-mounted display (“HMD”). Also, in an embodiment, the display device 1 may be used as a display in an instrument cluster of a vehicle, a center information display (“CID”) disposed (e.g., mounted) on a center fascia or a dashboard of a vehicle, a room mirror display replacing a side-view mirror of a vehicle, or a car headrest monitor provided for rear-seat entertainment.

As shown in FIG. 1, the shape of the display apparatus 1 may be substantially a rectangle. As shown in FIG. 1, e.g., the display apparatus 1 may have a quadrangular planar shape, e.g., rectangular planar shape having long sides extending in a first direction (e.g., an x direction or a -x direction) and short sides extending in a second direction (e.g., a y direction or a -y direction). In an embodiment, a portion, in which the long side extending in the first direction (e.g., the x direction or the -x direction) meets the short side extending in the second direction (e.g., the y direction or the -y direction), may have a right-angled shape or a round shape with predetermined curvature. The planar shape of the display apparatus 1 is not limited to the rectangle and may be a polygon, a circle, or an oval.

The display apparatus 1 may include a display area DA and a peripheral area PA. In the display area DA, images may be displayed. In the display area DA, a plurality of pixels PX may be arranged. The display apparatus 1 may provide images by light emitted from the pixels PX. Each pixel PX may emit light by a display element. In an embodiment, each pixel PX may emit red light, green light, or blue light. In an embodiment, each pixel PX may emit red light, green light, blue light, or white light.

The peripheral area PA is an area where no images are displayed and may be a non-display area. The peripheral area PA may at least partially surround the display area DA. In an embodiment, the peripheral area PA may surround an entirety of the display area DA, for example. In the peripheral area PA, drivers which provide electrical signals to the pixels PX, power lines which supply power to the pixels PX, or the like may be arranged. In an embodiment, a scan driver which applies scan signals to the pixels PX may be disposed in the peripheral area PA, for example. Also, a data driver which applies data signals to the pixels PX may be disposed in the peripheral area PA.

In an embodiment, the peripheral area PA may include a pad area PDA to which the display circuit board 40 is connected.

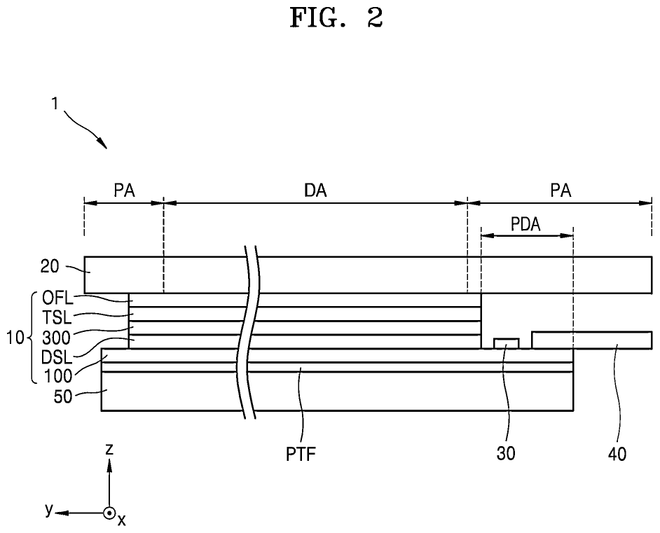

FIG. 2 is a schematic side view of an embodiment of a portion of a display apparatus.

Referring to FIG. 2, the display apparatus 1 may include a display panel 10, a cover window 20, a display driver 30, a display circuit board 40, a cushion layer 50, and a protective film PTF.

The display panel 10 may display information processed in the display apparatus 1. In an embodiment, the display panel 10 may display information regarding an execution screen of an application executed on the display apparatus 1, or user interface (“UI”) information or graphics user interface (“GUI”) information according to the information regarding the execution screen, for example.

The display panel 10 may include a display element. In an embodiment, the display panel 10 may be an organic light-emitting display panel using organic light-emitting diodes (“OLEDs”), a micro light-emitting diode (“LED”) display panel using micro-LEDs, a quantum dot light-emitting display panel using quantum dot LEDs including quantum dot emission layers, or an inorganic light-emitting display panel using inorganic LEDs including inorganic semiconductors, for example. Hereinafter, a case where the display panel 10 is an organic light-emitting display panel using OLEDs as display elements is described in detail.

The display panel 10 may include the substrate 100 and a multilayered film disposed over the substrate 100. In an embodiment, the display panel 10 may include the substrate 100, a display layer DSL, an encapsulation layer 300, a touch sensor layer TSL, and an optical functional layer OFL. In this case, the display area DA and the peripheral area PA may be defined in the substrate 100 and/or the multilayered film. In an embodiment, it may be described that the substrate 100 includes the display area DA and the peripheral area PA, for example. Also, the peripheral area PA may include the pad area PDA projected from a side of the display area DA.

The substrate 100 may include polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. In an embodiment, the substrate 100 may have a multilayered structure that includes a base layer including the above polymer resin and a barrier layer (not shown). The substrate 100 including polymer resin may be flexible, rollable, or bendable.

The display layer DSL may be disposed over the substrate 100. The display layer DSL may include pixel circuits and display elements. In this case, each pixel circuit may be connected to each display element. The pixel circuit may include a thin-film transistor and a storage capacitor. Therefore, the display layer DSL may include a plurality of display elements, a plurality of thin-film transistors, and a plurality of storage capacitors. Also, the display layer DSL may further include a plurality of insulating layers interposed therebetween.

The encapsulation layer 300 may be disposed over the display layer DSL. The encapsulation layer 300 may be disposed over the display element and cover the same. In an embodiment, the encapsulation layer 300 may include at least one inorganic encapsulation layer and at least one organic encapsulation layer. At least one inorganic encapsulation layer may include one or more inorganic materials selected from among aluminum oxide (Al₂O₃), titanium oxide (TiO₂), tantalum oxide (Ta₂O₅), zinc oxide (ZnO), silicon oxide (SiO₂), silicon nitride (SiNₓ), and silicon oxynitride (SiON). At least one organic encapsulation layer may include a polymer-based material. The polymer-based material may include acrylic resin, epoxy-based resin, polyimide, polyethylene, or the like. In an embodiment, at least one organic encapsulation layer may include acrylate.

The touch sensor layer TSL may be disposed over the encapsulation layer 300. The touch sensor layer TSL may sense coordinate information according to an external input, e.g., a touch event. The touch sensor layer TSL may include a sensor electrode and touch lines connected to the sensor electrode. The touch sensor layer TSL may sense an external input in a self-capacitive manner or a mutual-capacitive manner.

The touch sensor layer TSL may be formed on the encapsulation layer 300. In an alternative embodiment, after the touch sensor layer TSL is separately formed on a touch substrate, the touch sensor layer TSL may be coupled to the encapsulation layer 300 by an adhesive layer, such as an optically clear adhesive (“OCA”). In an embodiment, the touch sensor layer TSL may be formed directly on the encapsulation layer 300, and in this case, no adhesive layer may be interposed between the touch sensor layer TSL and the encapsulation layer 300.

The optical functional layer OFL may be disposed over the touch sensor layer TSL. The optical functional layer OFL may reduce the reflectivity of light (external light) that is incident towards the display apparatus 1 from the outside and/or may improve the color purity of light emitted from the display apparatus 1. In an embodiment, the optical functional layer OFL may include a retarder and a polarizer. The retarder may be of a film type or a liquid crystal coating type and may include a λ/2 retarder and/or a λ/4 retarder. The polarizer may also be of a film type or a liquid crystal coating type. The film type may include a stretched synthetic resin film, and the liquid crystal coating type may include liquid crystals arranged in a predetermined arrangement. The retarder and the polarizer may further include a protective film.

In another embodiment, the optical functional layer OFL may include a black matrix and color filters. The color filters may be arranged considering colors of light respectively emitted from the pixels of the display apparatus 1. Each color filter may include a red, green, or blue pigment or dye. In an alternative embodiment, each color filter may further include quantum dots in addition to the above pigment or dye. In an alternative embodiment, some of the color filters may not include the above pigment or dye and may include scattered particles, such as TiO₂.

In another embodiment, the optical functional layer OFL may include a destructive interference structure. The destructive interference structure may include a first reflection layer and a second reflection layer arranged in different layers. First reflection light and second reflection light, which are respectively reflected from the first reflection layer and the second reflection layer, may destructively interfere with each other, and the reflectivity of external light may decrease accordingly.

The cover window 20 may be disposed over the display panel 10. The cover window 20 may protect the display panel 10. In an embodiment, the cover window 20 may be a flexible window. The cover window 20 may be easily bent by external force without the generation of cracks, etc., thus providing protection for the display panel 10. The cover window 20 may include at least one of glass, sapphire, and plastic. The cover window 20 may be, e.g., ultra-thin glass (“UTG”) or colorless polyimide (“CPI”). In an embodiment, the cover window 20 may have a structure in which a flexible polymer layer is disposed on one surface of a glass substrate, or may only include a polymer layer.

The cover window 20 may be attached to the display panel 10 by an adhesive member. The adhesive member may be a colorless adhesive member, such as an OCA. Besides, the adhesive member may include well-known adhesive materials. Such an adhesive member may be formed on the upper portion of the display panel 10 in various manner; for example, a film-type adhesive member may be attached to the upper portion of the display panel 10, or a material-type adhesive member may be applied to the upper portion of the display panel 10.

The display driver 30 may be disposed over the display panel 10, e.g., the substrate 100. The display driver 30 may receive control signals and power voltages and generate and output signals and voltages for driving the display panel 10. The display driver 30 may include an integrated circuit (“IC”). In an embodiment, the display driver 30 may be disposed in the peripheral area PA, e.g., the pad area PDA.

The display circuit board 40 may be electrically connected to the display panel 10. In an embodiment, the display circuit board 40 may be connected to the display panel 10 in the pad area PDA of the display panel 10. In an embodiment, the display circuit board 40 may be a rigid printed circuit board (“PCB”) that is rigid and thus hardly bent. However, the disclosure is not limited thereto and do not exclude the possibility that the display circuit board 40 is a flexible printed circuit board (“FPCB”).

Although not shown, various drivers may be arranged on the display circuit board 40. In an embodiment, a touch sensor driver may be disposed on the display circuit board 40, for example. The touch sensor driver may include an IC. The touch sensor driver may be electrically connected to sensor electrodes of the touch sensor layer TSL of the display panel 10 through the display circuit board 40.

In addition to this, a power supply may be additionally disposed on the display circuit board 40. The power supply may supply a driving voltage for driving the pixels of the display panel 10 and the display driver 30.

The protective film PTF may be patterned and attached to a lower surface of the substrate 100. That is, the protective film PTF may be disposed between the substrate 100 and the cushion layer 50.

In an embodiment, the cushion layer 50 may be disposed under the display panel 10, particularly, the substrate 100. The cushion layer 50 may prevent damage to the display panel 10 by absorbing external impact. The cushion layer 50 may include polymer resin, such as polyurethane, polycarbonate, polypropylene, or polyethylene or an elastic material, e.g., a sponge, which is obtained by foam-molding rubber, urethane-based materials or acryl-based materials.

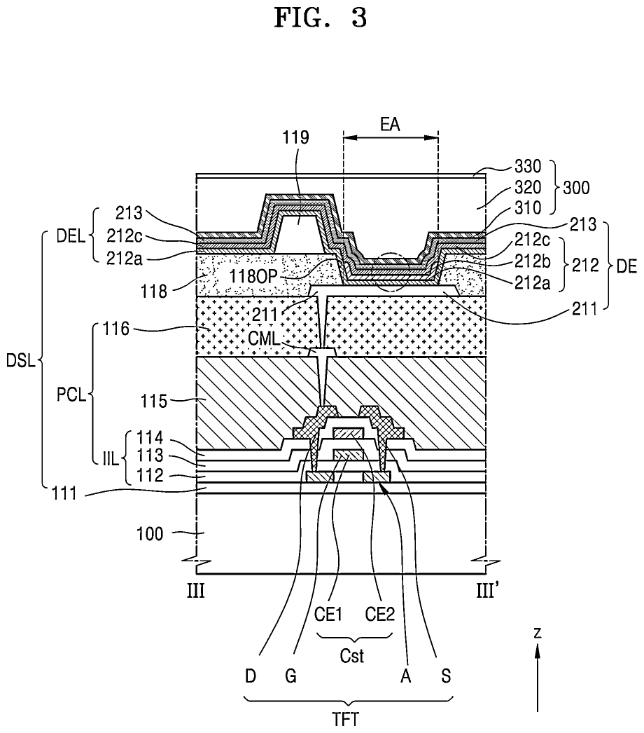

FIG. 3 is a schematic cross-sectional view taken along line III-III′ of FIG. 1 and showing an embodiment of a portion of the display apparatus.

Referring to FIG. 3, the display apparatus 1 may include a display panel 10. The display panel 10 may include a substrate 100, a display layer DSL, an encapsulation layer 300, a touch sensor layer TSL, and an optical functional layer OFL. In FIG. 3, the touch sensor layer TSL and the optical functional layer OFL are omitted for convenience of explanation.

The display layer DSL may be disposed over the substrate 100. The display layer DSL may include a buffer layer 111, a pixel circuit layer PCL, and a display element layer DEL.

The substrate 100 may include glass or polymer resin, such as polyethersulfone, polyarylate, polyetherimide, polyethylene naphthalate, polyethylene terephthalate, polyphenylene sulfide, polyimide, polycarbonate, cellulose triacetate, or cellulose acetate propionate. The substrate 100 including polymer resin may be flexible, rollable, or bendable. The substrate 100 may have a multilayered structure that includes a base layer including the above polymer resin and a barrier layer (not shown).

The buffer layer 111 may include inorganic insulating materials, such as SiNₓ, SiON, and SiO₂ and may be a layer or layers including the inorganic insulating materials.

The pixel circuit layer PCL may be disposed over the buffer layer 111. The pixel circuit layer PCL may include a transistor TFT included in a pixel circuit, and an inorganic insulating layer IIL, a first planarization layer 115, and a second planarization layer 116 which are disposed under and/or above components of the transistor TFT. The inorganic insulating layer IIL may include a first gate insulating layer 112, a second gate insulating layer 113, and an inter-insulating layer 114.

The transistor TFT may include a semiconductor layer A, and the semiconductor layer A may include polysilicon. In an alternative embodiment, the semiconductor layer A may include amorphous silicon, an oxide semiconductor, an organic semiconductor, or the like. The semiconductor layer A may include a channel area and a source area and a drain area located on opposite sides of the channel area. A gate electrode G may overlap the channel area.

The gate electrode G may include a low-resistive metal material. The gate electrode G may include a conductive material including molybdenum (Mo), aluminum (Al), copper (Cu), or titanium (Ti) and may be a layer or layers including the above material.

The first gate insulating layer 112 between the semiconductor layer A and the gate electrode G may include an inorganic insulating material, such as SiO₂, SiNₓ, SiON, Al₂O₃, TiO₂, Ta₂O₅, HfO₂, or ZnOₓ. ZnOₓ may be ZnO and/or ZnO₂.

The second gate insulating layer 113 may cover the gate electrode G. Similar to the first gate insulating layer 112, the second gate insulating layer 113 may include an inorganic insulating material, such as SiO₂, SiNₓ, SiON, Al₂O₃, TiO₂, Ta₂O₅, HfO₂, or ZnOₓ. ZnOₓ may be ZnO and/or ZnO₂.

An upper electrode CE2 of a storage capacitor Cst may be disposed over the second gate insulating layer 113. The upper electrode CE2 may overlap the gate electrode G disposed thereunder. In this case, the gate electrode G and the upper electrode CE2, which overlap each other with the second gate insulating layer 113 therebetween, may form the storage capacitor Cst of the pixel circuit. That is, the gate electrode G may function as a lower electrode CE1 of the storage capacitor Cst. As described, the storage capacitor Cst may overlap the transistor TFT. In some embodiments, the storage capacitor Cst may not overlap the transistor TFT.

The upper electrode CE2 may include Al, platinum (Pt), palladium (Pd), silver (Ag), magnesium (Mg), gold (Au), nickel (Ni), neodymium (Nd), iridium (Ir), chromium (Cr), calcium (Ca), Mo, Ti, tungsten (W), and/or Cu and may be a layer or layers including the above material.

The inter-insulating layer 114 may cover the upper electrode CE2. The inter-insulating layer 114 may include SiO₂, SiNₓ, SiON, Al₂O₃, TiO₂, Ta₂O₅, HfO₂, ZnOₓ, or the like. ZnOₓ may be ZnO and/or ZnO₂. The inter-insulating layer 114 may be a layer or layers including the above inorganic insulating material.

A drain electrode D and a source electrode S may each be disposed over the inter-insulating layer 114. The drain electrode D and the source electrode S may each include a material with relatively good conductivity. The drain electrode D and the source electrode S may each include a conductive material including Mo, Al, Cu, or Ti and may be a layer or layers including the above material. In an embodiment, the drain electrode D and the source electrode S may have a multilayered structure of Ti/Al/Ti.

The first planarization layer 115 may cover the drain electrode D and the source electrode S. The first planarization layer 115 may include an organic insulating layer. The first planarization layer 115 may include organic insulating materials, such as a general-purpose polymer such as polymethylmethacrylate (“PMMA”) or polystyrene (“PS”), a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and any combinations thereof.

A connection electrode CML may be disposed over the first planarization layer 115. In this case, the connection electrode CML may be connected to the drain electrode D or the source electrode S through a contact hole in the first planarization layer 115. The connection electrode CML may include a material with relatively good conductivity. The connection electrode CML may include a conductive material including Mo, Al, Cu, or Ti and may be a layer or layers including the above material. In an embodiment, the connection electrode CML may have a multilayered structure of Ti/Al/Ti.

The second planarization layer 116 may cover the connection electrode CML. The second planarization layer 116 may include an organic insulating layer. The second planarization layer 116 may include organic insulating materials, such as a general-purpose polymer such as PMMA or PS, a polymer derivative having a phenol-based group, an acryl-based polymer, an imide-based polymer, an aryl-ether-based polymer, an amide-based polymer, a fluorine-based polymer, a p-xylene-based polymer, a vinyl alcohol-based polymer, and any combinations thereof.

The display element layer DEL may be disposed over the pixel circuit layer PCL. The display element layer DEL may include a display element DE. The display element DE may be an organic light-emitting diode (“OLED”). A pixel electrode 211 of the display element DE may be electrically connected to the connection electrode CML through a contact hole in the second planarization layer 116.

The pixel electrode 211 may include conductive oxide, such as indium tin oxide (“ITO”), indium zinc oxide (“IZO”), ZnO, indium oxide (In₂O₃), indium gallium oxide (“IGO”), or aluminum zinc oxide (“AZO”). In an embodiment, the pixel electrode 211 may include a reflection film including Ag, Mg, Al, Pt, Pd, Au, Ni, Nd, Ir, Cr, or any combinations thereof. In another embodiment, the pixel electrode 211 may further include films including ITO, IZO, ZnO, or In₂O₃ on/under the above reflection film.

A pixel-defining layer 118 defining an opening 118OP may be disposed over the pixel electrode 211, the opening 118OP exposing a central portion of the pixel electrode 211. The pixel-defining layer 118 may include an organic insulating material and/or an inorganic insulating material. The opening 118OP may define an emission area EA of light emitted from the display element (hereinafter, also referred to as an emission area)

DE. In an embodiment, the width of the opening 118OP may correspond to that of the emission area EA of the display element DE, for example.

A spacer 119 may be disposed over the pixel-defining layer 118. The spacer 119 may prevent damage to the substrate 100 in the method of manufacturing a display apparatus. When the display panel is manufactured, a mask sheet may be used to deposit a deposition material on the substrate 100. In this case, the spacer 119 may prevent defects, such as damage to a portion of the substrate 100 or breakage of the substrate 100, where such defects may occur when the mask sheet enters the opening 118OP of the pixel-defining layer 118 or adheres to the pixel-defining layer 118.

The spacer 119 may include an organic insulating material, such as polyimide. In an alternative embodiment, the spacer 119 may include an inorganic insulating material, such as SiNₓ or SiO₂, or both an organic insulating material and an inorganic insulating material.

In an embodiment, the spacer 119 may include a different material from the pixel-defining layer 118. In an alternative embodiment, in another embodiment, the spacer 119 may include the same material as that of the pixel-defining layer 118, and in this case, the pixel-defining layer 118 and the spacer 119 may be formed together through a mask process using a halftone mask, etc.

An intermediate layer 212 may be disposed over the pixel-defining layer 118. The intermediate layer 212 may include an emission layer 212b disposed in the opening 118OP of the pixel-defining layer 118. The emission layer 212b may include a high-molecular-weight or low-molecular-weight organic material emitting a predetermined color of light.

A first functional layer 212a and a second functional layer 212c may be disposed under and above the emission layer 212b. The first functional layer 212a may include, e.g., a hole transport layer (“HTL”) or both an HTL and a hole injection layer (“HIL”). The second functional layer 212c may be disposed over the emission layer 212b and optional. The second functional layer 212c may include an electron transport layer (“ETL”) and/or an electron injection layer (“EIL”). The first functional layer 212a and/or the second functional layer 212c may each be a common layer formed to cover an entirety of the substrate 100 like an opposite electrode 213 described below.

The opposite electrode 213 may include a conductive material having a relatively low work function. In an embodiment, the opposite electrode 213 may include a transparent (or translucent) layer including Ag, Mg, Al, Pt, Pd, Au, Ni, Nd, Ir, Cr, lithium (Li), calcium (Ca), or any alloys thereof, for example. In an alternative embodiment, the opposite electrode 213 may further include a layer including ITO, IZO, ZnO, or In₂O₃ on the transparent (or translucent) layer including the above material.

In some embodiments, a capping layer (not shown) may be further disposed over the opposite electrode 213. The capping layer may include LiF, an inorganic material, and/or an organic material.

The encapsulation layer 300 may be disposed over the opposite electrode 213. The encapsulation layer 300 may be disposed over the display element layer DEL and cover the same. The encapsulation layer 300 may include at least one inorganic encapsulation layer and at least one organic encapsulation layer, and in an embodiment, FIG. 3 shows that the encapsulation layer 300 includes a first inorganic encapsulation layer 310, an organic encapsulation layer 320, and a second inorganic encapsulation layer 330 which are sequentially stacked.

The first inorganic encapsulation layer 310 and the second inorganic encapsulation layer 330 may each include one or more inorganic materials selected from among Al₂O₃, TiO₂, Ta₂O₅, HfO₂, ZnOₓ, SiO₂, SiNₓ, and SiON. The organic encapsulation layer 320 may include a polymer-based material. The polymer-based material may include acryl-based resin, epoxy-based resin, polyimide, polyethylene, or the like. In an embodiment, the organic encapsulation layer 320 may include acrylate. The organic encapsulation layer 320 may be formed by curing a monomer or applying a polymer. The organic encapsulation layer 320 may be transparent.

Although not shown on the encapsulation layer 300, the touch sensor layer described above may be disposed, and an optical functional layer may be disposed over the touch sensor layer.

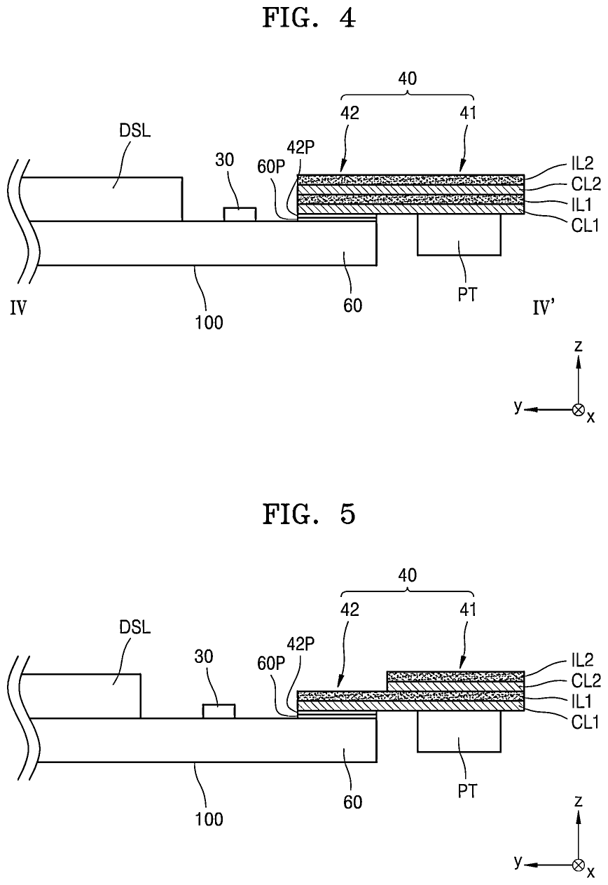

FIG. 4 is a schematic cross-sectional view taken along line IV-IV′ of FIG. 1 and showing an embodiment of the display apparatus.

Referring to FIGS. 1 and 4, as described above, the display apparatus 1 may include the display area DA and the peripheral area PA surrounding at least a portion of the display area DA. In an embodiment, the display area DA may have a quadrangular shape, e.g., rectangular shape. In this case, the display area DA may be defined by a pair of parallel first edges extending in the first direction (e.g., the x direction of FIG. 1) and a pair of parallel second edges extending in the second direction (e.g., the y direction of FIG. 1). The peripheral area PA may be disposed to surround the first and second edges of the display area DA. In this case, the peripheral area PA may include an edge of the display area DA, e.g., the pad area PDA protruding from the first edge. In the pad area PDA, the display panel 10, e.g., the substrate 100, may be electrically connected to the display circuit board 40.

The display panel 10, e.g., the substrate 100, may include a panel protrusion 60 protruding outwards from a portion of the periphery, e.g., a first edge S1, of the display area DA. In an embodiment, the panel protrusion 60 may be provided in the plural, and in this case, the panel protrusions 60 may be spaced apart from each other along the first edge S1. In an embodiment, as shown in FIG. 1, there may be two panel protrusions 60 or two or more panel protrusions 60, for example. Hereinafter, for convenience of explanation, there are two panel protrusions 60.

As shown in FIG. 1, the panel protrusion 60 may have a substantially tapered quadrangular shape, e.g., a substantially tapered rectangular shape, but is not limited thereto. The panel protrusion 60 may have various shapes, e.g., a semielliptical shape protruding from the first edge S1 and decreasing in width. In addition, the panel protrusion 60 may also have a quadrangular shape, e.g., rectangular shape with a uniform width.

As described above, the display driver 30 may be disposed on the panel protrusion 60. Also, a first pad 60P may be disposed on the panel protrusion 60. The first pad 60P may contact a second pad 42P described below and be electrically connected thereto.

The display circuit board 40 may contact the panel protrusion 60 and be electrically connected thereto. In an embodiment, the display circuit board 40 may be a rigid PCB that is rigid and hardly bent. The display circuit board 40 may include a body portion 41, a connecting portion 42, and a board protrusion 43.

The body portion 41 may extend along a portion of the periphery of the display area DA. In an embodiment, the body portion 41 may extend along the first edge S1 extending in the first direction (e.g., the x direction of FIG. 1), for example. In this case, the body portion 41 may be spaced apart from the first edge S1 in the second direction (e.g., the y direction of FIG. 1) that crosses an extension direction of the first edge S1. In an embodiment, the body portion 41 may extend in parallel with the first edge S1. Also, in an embodiment, the extended length of the body portion 41 in the first direction may be less than the length of the first edge S1 in the first direction. As described below, such a length may provide a space where components, such as hinges, may be connected when the display apparatus 1 is coupled to the electronic device.

The connecting portion 42 may be extended to the body portion 41 and overlap the panel protrusion 60. The connecting portion 42 may include the second pad 42P on a portion of the connecting portion 42 overlapping the panel protrusion 60. The second pad 42P may contact the first pad 60P and electrically connect the connecting portion 42 to the panel protrusion 60. In addition, the connecting portion 42 may be electrically connected to the display panel 10 through the panel protrusion 60.

In an embodiment, the connecting portion 42 may have a shape protruding from the body portion 41. However, the disclosure is not limited thereto, and in another embodiment, the connecting portion 42 may not protrude and may be integrated into the body portion 41. In this case, it may be described that the second pad 42P may be disposed on the body portion 41.

The number of connecting portions 42 may correspond to the number of panel protrusions 60. In an embodiment, when the number of panel protrusions 60 is two as shown in FIG. 1, the number of connecting portions 42 may also be two, for example. In this case, the connecting portions 42 may be spaced apart from each other in the extension direction of the body portion 41, that is, the first direction. In an embodiment, as shown in FIG. 1, the connecting portion 42 may have a substantially tapered quadrangular shape, e.g., substantially tapered rectangular shape, but the shape is not limited thereto.

The board protrusion 43 may protrude from the body portion 41. In an embodiment, the board protrusion 43 may protrude towards a concave area CA defined between multiple panel protrusions 60. In other words, the board protrusion 43 may be disposed between the panel protrusions 60. Also, the board protrusion 43 may be disposed between the connecting portions 42. FIG. 1 shows one board protrusion 43, but when there are multiple panel protrusions 60, e.g., three panel protrusions 60, there may be two board protrusions 43 arranged between three panel protrusions 60. In this case, the panel protrusions 60 and the board protrusions 43 may be alternately arranged. The connecting portions 42 and the board protrusions 43 may also be alternately arranged.

In the plan view, the board protrusion 43 may not contact or overlap the display panel 10 and may be disposed in a space between the panel protrusions 60. On the board protrusion 43, various parts PT that may be disposed (e.g., mounted) on the display circuit board 40 may be arranged. Accordingly, a dead space in the second direction may decrease. Also, a protrusion length L1 of the board protrusion 43 from the body portion 41 may be greater than a protrusion length L2 of the connecting portion 42 from the body portion 41. Therefore, a greater area may be secured on the board protrusion 43 to mount the parts PT.

Also, the board protrusion 43 may have a quadrangular shape, e.g., rectangular shape that is substantially tapered according to the shape of the panel protrusion 60, but the disclosure is not limited thereto. The board protrusion 43 may have various shapes, e.g., a semielliptical shape protruding from the body portion 41 and decreasing in width. In addition, the board protrusion 43 may also have a quadrangular shape, e.g., rectangular shape with a uniform width.

Also, the board protrusion 43, the connecting portion 42, and the body portion 41 may be unitary with one another. The description that the board protrusion 43, the connecting portion 42, and the body portion 41 are unitary may indicate that the board protrusion 43, the connecting portion 42, and the body portion 41 include a stack structure of the display circuit board 40 including at least one conductive layer and at least one insulating layer and are continuously connected.

Referring back to FIG. 4, the display circuit board 40 may include at least one conductive layer and at least one insulating layer. In an embodiment, the display circuit board 40 may include a first conductive layer CL1, a first insulating layer IL1, a second conductive layer CL2, and a second insulating layer IL2 which are sequentially arranged in a thickness direction of the display circuit board 40 (e.g., a z direction of FIG. 4). That is, the first insulating layer IL1 may be disposed between the first conductive layer CL1 and the second conductive layer CL2, and the second insulating layer IL2 may be arranged to cover the second conductive layer CL2. FIG. 4 shows that the display circuit board 40 includes two conductive layers and two insulating layers, but the disclosure is not limited thereto. In an embodiment, it may be understood that the display circuit board 40 may include two or more conductive layers and two or more insulating layers, for example.

The first insulating layer IL1 and the second insulating layer IL2 may maintain the rigidity of the display circuit board 40 and protect signals from the outside. In addition, the first insulating layer IL1 and the second insulating layer IL2 may prevent the generation of cracks in the first conductive layer CL1 and the second conductive layer CL2. The first insulating layer IL1 and the second insulating layer IL2 may include polyimide.

The first conductive layer CL1 and the second conductive layer CL2 may include conductive materials. In an embodiment, the first conductive layer CL1 and the second conductive layer CL2 may include Cu, for example.

In an embodiment, the stack structure may be identically applied across the body portion 41, the connecting portion 42, and the board protrusion 43. In other words, the body portion 41, the connecting portion 42, and the board protrusion 43 may include the first conductive layer CL1, the first insulating layer IL1, the second conductive layer CL2, and the second insulating layer IL2. Also, the respective conductive layers of the body portion 41, the connecting portion 42, and the board protrusion 43 may be continuously extended.

In this case, the first conductive layer CL1 of the connecting portion 42 may include the second pad 42P and contact the first pad 60P of the panel protrusion 60, thus being electrically connected to the first pad 60P. Also, parts PT may be disposed (e.g., mounted) on a surface of the first conductive layer CL1 of the body portion 41, e.g., the lower surface (a surface in the-z direction of FIG. 4). Parts PT may also be disposed (e.g., mounted) on a surface, e.g., a lower surface, of the first conductive layer CL1 of the board protrusion 43.

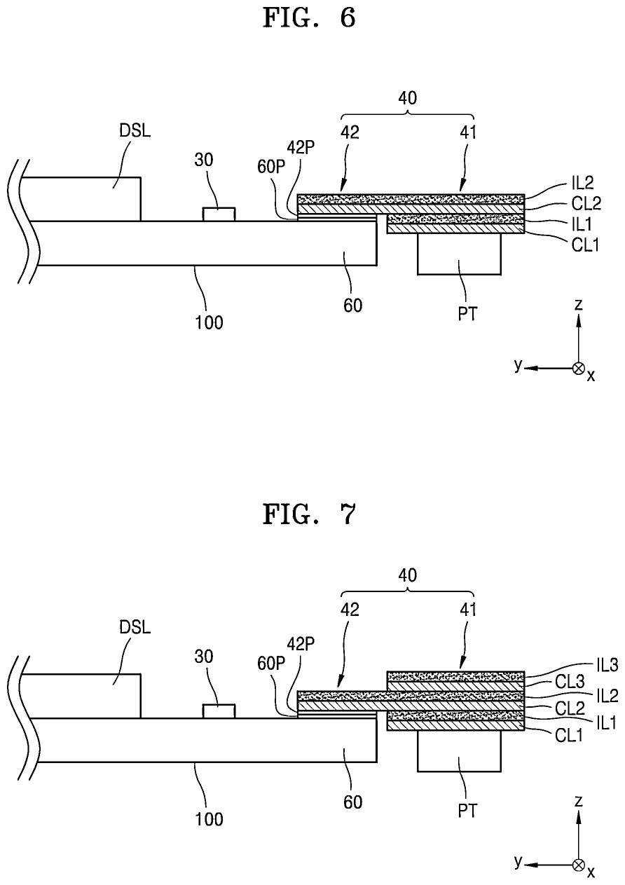

FIGS. 5 to 7 are schematic cross-sectional views of an embodiment of a display apparatus similar to the embodiment of FIG. 4. The display apparatus in the illustrated embodiments is similar to the display apparatus described above, and thus, a difference therebetween is mainly described.

Referring to FIG. 5, the display circuit board 40 may include at least one conductive layer and at least one insulating layer. In an embodiment, the body portion 41 may include a first conductive layer CL1, a first insulating layer IL1, a second conductive layer CL2, and a second insulating layer IL2 which are sequentially arranged in a thickness direction of the body portion 41 (e.g., a z direction of FIG. 5). That is, the first insulating layer IL1 may be disposed between the first conductive layer CL1 and the second conductive layer CL2, and the second insulating layer IL2 may be disposed to cover the second conductive layer CL2. Also, the board protrusion 43 may have the same stack structure as the body portion 41. FIG. 5 shows that the body portion 41 includes two conductive layers and two insulating layers, but the disclosure is not limited thereto. In an embodiment, it may be understood that the body portion 41 may include two or more conductive layers and two or more insulating layers, for example. Hereinafter, for convenience of explanation, the case of FIG. 5 is mainly described.

The connecting portion 42 may be formed as at least one of the conductive layers included in the body portion 41 and the board protrusion 43 extends. In an embodiment, as shown in FIG. 5, the body portion 41 may include the first conductive layer CL1, the first insulating layer IL1, the second conductive layer CL2, and the second insulating layer IL2, for example. The conductive layer, which is the lowermost among the conductive layers, e.g., the first conductive layer CL1, may protrude from the body portion 41 and form the connecting portion 42. Also, the first insulating layer IL1 covering the first conductive layer CL1 may protrude from the body portion 41 and form the connecting portion 42. In this case, other conductive layers, e.g., the second conductive layer CL2, may not protrude from the body portion 41 and not form the connecting portion 42.

As a result, the thickness of the connecting portion 42 may be less than that of the body portion 41. As the number of layers forming the connecting portion 42 increases, the modulus and elongation may increase. Accordingly, when the display circuit board 40 is attached and connected to the display panel 10 through the connecting portion 42, connection defects, such as the separation of the first pad 60P from the second pad 42P, may occur because of increased contraction and expansion. In an embodiment, as the connecting portion 42 is formed to be thinner than the body portion 41, that is, to include a smaller number of conductive layers than the body portion 41, the modulus and elongation may decrease, and contact and connection characteristics may be improved when attaching the display circuit board 40.

Referring to FIG. 6, the connecting portion 42 may be formed as at least one of the conductive layers included in the body portion 41 and the board protrusion 43 extends. In an embodiment, as shown in FIG. 6, the body portion 41 may include the first conductive layer CL1, the first insulating layer IL1, the second conductive layer CL2, and the second insulating layer IL2, for example. The conductive layer, which is the uppermost among the conductive layers, e.g., the second conductive layer CL2, may protrude from the body portion 41 and form the connecting portion 42. Also, the second insulating layer IL2 covering the second conductive layer CL2 may protrude from the body portion 41 and form the connecting portion 42. In this case, other conductive layers, e.g., the first conductive layer CL1, may not protrude from the body portion 41 and not form the connecting portion 42.

Referring to FIG. 7, the connecting portion 42 may be formed as at least one of the conductive layers included in the body portion 41 and the board protrusion 43 extends. In an embodiment, as shown in FIG. 7, the body portion 41 may include the first conductive layer CL1, the first insulating layer IL1, the second conductive layer CL2, the second insulating layer IL2, the third conductive layer CL3, and the third insulating layer IL3, for example. The second conductive layer CL2, which is the conductive layer disposed in the middle of the conductive layers and neither at the top nor the bottom, may protrude from the body portion 41 and form the connecting portion 42. Also, the second insulating layer IL2 covering the second conductive layer CL2 may protrude from the body portion 41 and form the connecting portion 42. In this case, other conductive layers, e.g., the first conductive layer CL1 and the third conductive layer CL3, may not protrude from the body portion 41 and not form the connecting portion 42.

FIG. 7 shows that the number of conductive layers included in the body portion 41 is three, but the disclosure is not limited thereto. In an embodiment, when the body portion 41 includes four or more conductive layers, that is, the first conductive layer, the second conductive layer, the third conductive layer, and the fourth conductive layer, the second conductive layer or the third conductive layer, which is disposed in the middle of the body portion 41 to form the connecting portion 42, may protrude from the body portion 41, for example. In an alternative embodiment, it may be understood that both the second conductive layer and the third conductive layer may protrude from the body portion 41 and form the connecting portion 42.

According to the embodiments, a non-display area may be reduced in a display apparatus. In addition, an area for parts disposed (e.g., mounted) on a display circuit board may be secured.

It should be understood that embodiments described herein should be considered in a descriptive sense only and not for purposes of limitation. Descriptions of features or advantages within each embodiment should typically be considered as available for other similar features or advantages in other embodiments. While embodiments have been described with reference to the drawing figures, it will be understood by those of ordinary skill in the art that various changes in form and details may be made therein without departing from the spirit and scope as defined by the following claims.

What is claimed is:

1. A display apparatus comprising:
a display panel comprising:
a plurality of panel protrusions protruding from an edge of a display area and arranged apart from each other along the edge of the display area; and
a display circuit board comprising:
a body portion spaced apart from the edge of the display area and extending along the edge of the display area;
a plurality of connecting portions spaced apart in an extension direction of the body portion and overlapping the plurality of panel protrusions; and
a board protrusion protruding from the body portion towards a concave area defined between the plurality of panel protrusions.

2. The display apparatus of claim 1, wherein the plurality of panel protrusions comprise a first pad, the plurality of connecting portions comprise a second pad on a portion of the plurality of connecting portions which overlaps the plurality of panel protrusions, and the first pad contacts and is electrically connected to the second pad.

3. The display apparatus of claim 1, wherein the plurality of connecting portions protrude from the body portion and overlap and are connected to the plurality of panel protrusions.

4. The display apparatus of claim 3, wherein a protrusion length of the board protrusion is greater than a protrusion length of the plurality of connecting portions.

5. The display apparatus of claim 1, wherein the plurality of connecting portions are provided in a number corresponding to a number of panel protrusions, and the board protrusion is disposed between the plurality of connecting portions.

6. The display apparatus of claim 1, wherein the body portion, the plurality of connecting portions, and the board protrusion are unitary with one another.

7. The display apparatus of claim 1, wherein, in a plan view, the board protrusion does not overlap the display panel and is spaced apart from the display panel.

8. The display apparatus of claim 1, wherein, in a plan view, the board protrusion has a tapered shape with a width decreasing away from the body portion.

9. The display apparatus of claim 1, wherein, in a plan view, the board protrusion has a rectangular shape with a width which is uniform away from the body portion.

10. The display apparatus of claim 1, wherein an extended length of the body portion is less than a length of the edge of the display area.

11. The display apparatus of claim 1, wherein the body portion and the plurality of connecting portions comprise a plurality of conductive layers stacked in a thickness direction of each of the body portion and plurality of connecting portions, and a conductive layer, which is a lowermost conductive layer among the plurality of conductive layers of the plurality of connecting portions, contacts and is electrically connected to the plurality of panel protrusions.

12. The display apparatus of claim 1, wherein the body portion and the plurality of connecting portions each comprise at least one conductive layer stacked in a thickness direction of each of the body portion and the plurality of connecting portions, and a number of the at least one conductive layer in the plurality of connecting portions is less than a number of the at least one conductive layer in the body portion.

13. The display apparatus of claim 12, wherein the at least one conductive layer of the body portion is provided in plural, and a conductive layer of a plurality of conductive layers of the body portion protrudes from the body portion to form the plurality of connecting portions and contacts and is electrically connected to the plurality of panel protrusions.

14. The display apparatus of claim 13, wherein the conductive layer protruding from the body portion is an uppermost conductive layer among the plurality of conductive layers.

15. The display apparatus of claim 13, wherein the conductive layer protruding from the body portion is a lowermost conductive layer among the plurality of conductive layers.

16. The display apparatus of claim 13, wherein the conductive layer protruding is a middle layer among the plurality of conductive layers.

17. A display circuit board connectable to a display panel, the display circuit board comprising:
a body portion extending in a direction;
a plurality of connecting portions protruding from the body portion and spaced apart from each other in an extension direction of the body portion, the plurality of connecting portions comprising:
a pad which is electrically connected to the display panel; and
a board protrusion protruding from the body portion between the plurality of connecting portions,.

18. The display circuit board of claim 17, wherein a protrusion length of the board protrusion is greater than a protrusion length of the plurality of connecting portions.

19. The display circuit board of claim 17, wherein the body portion, the plurality of connecting portions, and the board protrusion are unitary with one another.

20. The display circuit board of claim 17, wherein the body portion comprises a plurality of conductive layers stacked in a thickness direction of the body portion, and one of the plurality of conductive layers protrudes from the body portion to form the plurality of connecting portions.
